(19) United States
(12) Patent Application Publication
(10) Pub. No.: US 2025/0251458 A1
(43) Pub. Date: Aug. 7, 2025

(54) METHOD OF IMPLEMENTING OPPORTUNISTIC BATTERY CAPACITY ALGORITHMS FOR A SYSTEM WITH MULTIPLE SUBPACKS

(71) Applicant: GM Global Technology Operations LLC, Detroit, MI (US)

(72) Inventors: Ryan C. Mansfield, Milford, MI (US); Alec Rounds, Commerce Twp., MI (US); Balin Kumar Shrivastava, Waterford, MI (US)

(21) Appl. No.: 18/429,756

(22) Filed: Feb. 1, 2024

(51) Int. Cl. G01R 31/388; G01R 31/364; H01M 10/42

(52) U.S. Cl. CPC G01R 31/388; G01R 31/364; H01M 10/4285

(57) ABSTRACT

An electrical system and method of operation is disclosed. The electrical system can be an energy storage device operating a load. A battery pack provides power to the electrical system. A processor determines a model of a power schedule of the electrical system, determines, using the model, a test time during operation of the electrical system for obtaining a parameter suitable for calculating a capacity of the battery pack, obtains the parameter of the battery pack at the test time, calculates the capacity of the battery pack using the parameter, and operates the electrical system based on the calculated capacity.

### INTRODUCTION

The subject disclosure relates to diagnosing an electrical system during operation and, more specifically, to a system and method for determining a capacity of a power source of the electrical system during its operation.

Various electrical systems are used in scenarios in which the system is operated either continuously or near-continuously. Examples of such electrical system include land and sea vehicles utilizing an electric or hybrid-electric means of propulsion (electrical trains, electrical ferries, etc.) as well as stationary energy storage systems, etc. In order to maintain the system, it is necessary to perform various diagnoses. However, many diagnostic operations, such as calculating a capacity of a power source of the electrical system, require that the sub-system be electrically disconnected. For these systems that are either continuously or near-continuously operated, it is therefore not possible to perform such diagnostic operations. Accordingly, it is desirable to provide a system and method by which a capacity of a power source can be determined without interrupting operation of the electrical system.

### SUMMARY

In one exemplary embodiment, a method of operating an electrical system is disclosed. A model of a power schedule of the electrical system is determined, the electrical system operating being powered by a battery pack. The model is used to determine a test time during operation of the electrical system for obtaining a parameter suitable for calculating a capacity of the battery pack. The parameter of the battery pack is obtained at the test time. The capacity of the battery pack is calculated using the parameter. The electrical system is operated based on the calculated capacity.

In addition to one or more of the features described herein, the method further includes obtaining the parameter using a data collection procedure that is one of interruptive of operation of the electrical system and non-interruptive of operation of the electrical system.

In addition to one or more of the features described herein, the method further includes obtaining the parameter by opening a contactor between the battery pack and the electrical system and determining a state of charge with the contactor open.

In addition to one or more of the features described herein, the battery pack is selected from a plurality of battery packs, further comprising isolating a selected battery pack and obtaining the parameter of the selected battery pack while operating the electrical system using non-isolated battery packs.

In addition to one or more of the features described herein, the method further includes operating the electrical system at a constant current, obtaining a first measurement of voltage, determining a current throughput of the battery pack, and obtaining a second measurement of voltage.

In addition to one or more of the features described herein, the constant current is about zero amps.

In addition to one or more of the features described herein, the method further includes selecting the test time from the model based on at least one of Global Positioning Satellite (GPS) telemetry, a time or distance traveled by the electrical system with no predicted changes in elevation, a time or distance travelled by the electrical system with no predicted stops, and a time or distance travelled by the electrical system with no predicted changes in load to the battery pack.

In another exemplary embodiment, an electrical system is disclosed. The electrical system includes a battery pack providing power to the electrical system, and a processor. The processor is configured to determine a model of a power schedule of the electrical system, determine, using the model, a test time during operation of the electrical system for obtaining a parameter suitable for calculating a capacity of the battery pack, obtain the parameter of the battery pack at the test time, calculate the capacity of the battery pack using the parameter, and operate the electrical system based on the calculated capacity.

In addition to one or more of the features described herein, the processor is further configured to obtain the parameter using a data collection procedure that is one of interruptive of operation of the electrical system and non-interruptive of operation of the electrical system.

In addition to one or more of the features described herein, the processor is further configured to obtain the parameter by opening a contactor between the battery pack and the electrical system and determine a state of charge with the contactor open.

In addition to one or more of the features described herein, the processor is further configured to select a battery pack from a plurality of battery packs, isolate the selected battery pack and obtain the parameter of the selected battery pack while operating the electrical system using non-isolated battery packs.

In addition to one or more of the features described herein, the processor is further configured to operate the electrical system at a constant current, obtain a first measurement of voltage, determine a current throughput of the battery pack, and obtain a second measurement of voltage.

In addition to one or more of the features described herein, the constant current is about zero amps.

In addition to one or more of the features described herein, the processor is further configured select the test time from the model based on at least one of Global Positioning Satellite (GPS) telemetry, a time or distance traveled by the electrical system with no predicted changes in elevation, a time or distance travelled by the electrical system with no predicted stops, and a time or distance travelled by the electrical system with no predicted changes in load to the battery pack.

In yet another exemplary embodiment, an energy storage device operating a load is disclosed. The energy storage device includes a battery pack providing power to the load and a processor. The processor is configured to determine a model of a power schedule of the energy storage device, determine, using the model, a test time during operation of the energy storage device for obtaining a parameter suitable for calculating a capacity of the battery pack, obtain the parameter of the battery pack at the test time, calculate the capacity of the battery pack using the parameter, and operate the energy storage device based on the calculated capacity.

In addition to one or more of the features described herein, the processor is further configured to obtain the parameter using a data collection procedure that is one of interruptive of operation of the energy storage device and non-interruptive of operation of the energy storage device.

In addition to one or more of the features described herein, the processor is further configured to obtain the parameter by opening a contactor between the battery pack and the load and determine a state of charge with the contactor open.

In addition to one or more of the features described herein, the processor is further configured to select a battery pack from a plurality of battery packs, isolate the selected battery pack and obtain the parameter of the selected battery pack while operating the load using the non-isolated battery packs.

In addition to one or more of the features described herein, the processor is further configured to operate the energy storage device at a constant current, obtain a first measurement of voltage, determine a current throughput of the battery pack, and obtain a second measurement of voltage.

In addition to one or more of the features described herein, the constant current is about zero amps.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a diagnostic system for diagnosing an electrical system in an illustrative embodiment;

FIG. 2 is a graph of a power schedule for the electrical system over time, in an illustrative embodiment;

FIG. 3 is a flowchart of a method for selecting a method for data collection at the electrical system to determine battery pack capacities;

FIG. 4 is a flowchart illustrating a method for testing a battery pack, in one embodiment;

FIG. 5 is a flowchart illustrating a method of determining a capacity for battery pack in another embodiment; and

FIG. 6 is a flowchart illustrating a method of testing a battery pack that is one of a plurality of battery packs of the electrical system.

### DETAILED DESCRIPTION

The following description is merely exemplary in nature and is not intended to limit the present disclosure, its application or uses. It should be understood that throughout the drawings, corresponding reference numerals indicate like or corresponding parts and features.

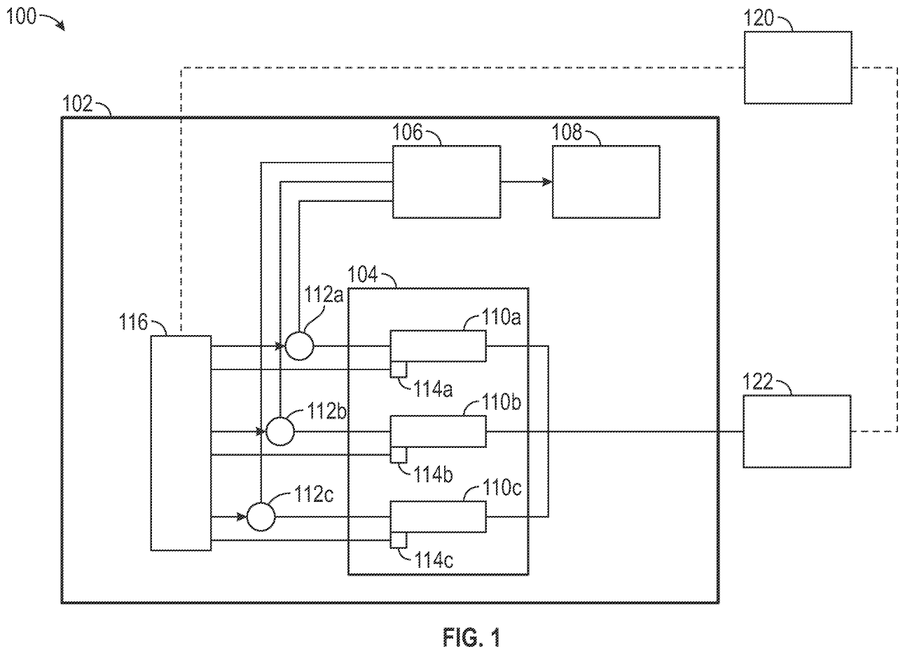

FIG. 1 is a diagnostic system 100 for diagnosing an electrical system 102 in an illustrative embodiment. The electrical system 102 includes a power source 104, an electrical motor 106 and a load 108 which can be a mechanical load, non-mechanical load, electric load, etc. The electrical motor 106 is powered by the power source 104 to run the load 108. The electrical system 102 is operated either continuously or near-continuously, such that the system is in use for a high percentage of time. A time period over which the electrical system 102 is operated is generally greater than a time between required diagnostic checks. In various embodiments, the electrical system 102 can be an electric vehicle such as an electrical train, an electric plane, an electrical freight vessel, an electric ferry, a stationary energy storage device, or other system designed for industrial, residential, and commercial uses.

The power source 104 includes one or more battery packs, which can be rechargeable energy storage sources (RESS). Each battery pack can include a plurality of sub-packs. For illustrative purposes only, the power source 104 includes a first battery pack 110a, a second battery pack 110b and a third battery pack 110c. Each battery pack is coupled to the electrical motor 106 via an associated switch or contactor. For example, first battery pack 110a is coupled via a first contactor 112a, second battery pack 110b is coupled via second contactor 112b, and third battery pack 110c is coupled via a third contactor 112c. Each battery pack also has an associated sensor which obtains various parameters indicative of a capacity of the battery pack. For example, a first sensor 114a is associated with the first battery pack 110a, a second sensor 114b is associated with the second battery pack 110b, and a third sensor 114c is associated with the third battery pack 110c. The sensors can include voltmeters, ammeters, etc.

A controller 116 controls operation of the contactors 112a, 112b, 112c and obtains measurements from the sensors 114a, 114b, 114c. The controller 116 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 116 may include a non-transitory computer-readable medium that stores instructions which, when processed by one or more processors of the controller 116, implement a method of obtaining a parameter of the battery pack for diagnostic purposes during operation of the electrical system, according to one or more embodiments detailed herein.

The controller 116 is in communication with a remote server 120. The controller 116 can similarly be used to schedule operations for obtaining a parameter of the battery pack of the electrical system 102. The remote server 120 stores a model of a schedule of operation of the electrical system 102 and communicates a signal to the controller 116 based on the model, thereby causing the controller to perform a diagnosis operation on the power source 104. The controller 116 can communicate the collected data to the remote server 120. The controller 116 and/or remote server 120 can calculate a capacity of the one or more battery packs from the collected data. Based on these capacity calculations, the remote server 120 can send a signal to a charging station 122 to schedule a charging operation. The remote server 120 can also send a signal to the controller 116 to indicate the scheduled charging.

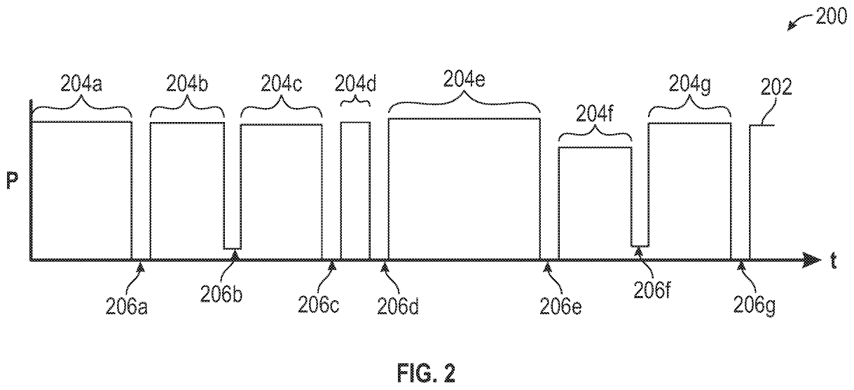

FIG. 2 is a graph 200 of a power schedule for the electrical system 102 over time, in an illustrative embodiment. Time (t) is shown along the abscissa and power (P) is shown along the ordinate axis as a percentage of full power. A curve 202 representative of the power schedule shows the power that is used by the electrical system 102 over time. The curve 202 includes high operating power periods 204a-204g during which the electrical system 102 is in high power use and low operating power periods 206a-206g during which the electrical system 102 is at rest or near rest. The curve 202 shows that the electrical system 102 is used nearly constantly and has very few breaks. In addition, each break (e.g., low operating power periods 206a-206g) is relatively short in comparison to the high operating power periods 204a-204g. During the high operating power periods 204a-204g, the electrical system 102 can operated at 100% power capability (e.g., high operating power periods 204a-204e and 204g) or at a near-100% power capability (e.g., low operating power period 204f). The low operating power periods 206a-206g can include periods during which the electrical system 102 is turned off (e.g., low operating power periods 206a, 206c, 206d, 206e and 206g) or periods during which the electrical system is operated at a low level, idle, etc. (e.g., low operating power periods 206b and 206f). The duration of the high operating power periods can be uniform. As shown in FIG. 2, the high operating power periods 204a-204g are non-uniform, as seen, for example, by high operating power periods 204d and 204e.

The shape of the curve 202 (i.e., power schedule) can be influenced by a plurality of parameters. For example, the power schedule for an electrical train can be affected by parameters such as a location of the train, a freight load, a change in elevation of the train over a given distance, a distance between train stops, weather conditions (e.g., temperature, precipitation), etc.

In various embodiments, these parameters can be used to develop a model of the power schedule. The model can be stored at the remote server 120 and can be used to determine suitable times at which parameters can be measured. The model can forecast patterns of future use for the electrical system 102, which can be used to select a time for data collection. This can be useful when the power schedule is not a preset schedule but is instead determined by outside parameters. For example, a weather forecast can be used with the model to determine an optimal time for obtaining measurements. Alternatively, when the electrical system has a preset power schedule, the model can reflect this schedule.

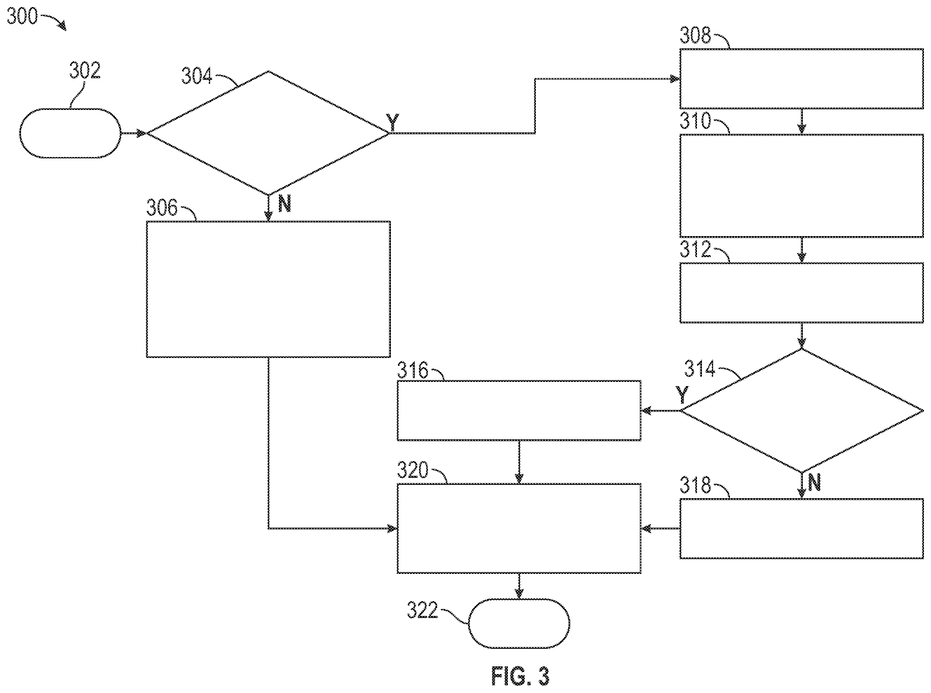

FIG. 3 is a flowchart 300 of a method for selecting a method for data collection at the electrical system 102 to determine battery pack capacities. The method begins at box 302. In box 304, with the electrical system 102 in operation, a decision is made whether a capacity calculation update for the battery is needed. If a capacity update is not needed, the method proceeds to box 306. In box 306, the electrical system 102 is operated normally, with parameters of the electrical system 102 being obtained using standard methods when the electrical system is at rest. From box 306, the method proceeds to box 320. In box 320, the capacity of the battery is calculated using the obtained parameters.

Returning to box 304, if a capacity calculation update is needed (while the electrical system 102 is running), the method proceeds to box 308. In box 308, a model of the power schedule is retrieved, and a future use of the electrical system 102 is determined using the model. In box 310, one or more test times are selected from the model for a given constraint. In one embodiment, the constraint includes time and the test time is selected to be performed within a given time frame (Δt). In another embodiment, the constraint includes mileage and the test time is selected to be performed before the electrical system traverses a given number of miles (Δx). In yet another embodiment, the constraint includes current throughput and the test time is selected to be performed before the electrical system experiences a given current throughput (ΔA).

The test time can be selected based on various parameters. As an example, for an electric train, a time or distance traveled can be selected such that there are no predicted changes in elevation of the train, no predicted stops for the train, no predicted changes in load for that train, etc. The test time can be selected based on a location of the train, which can be obtained from Global Positioning Satellite (GPS) data. The location of the train can be used to anticipate a window time in which there is little or no change in elevation, no stops, no additional loads, etc. In box 312, a method of measuring a parameter for the capacity calculation is selected.

In box 314, a determination is made whether a measurement procedure can be performed at the test time that does not interrupt operation of the electrical system 102. If a procedure can be selected that does not interrupt operation of the electrical system 102, the method proceeds to box 316. In box 316, the non-interruptive procedure is performed to obtain the parameters. Returning to box 314, if a non-interruptive procedure is not available, the method proceeds to box 318. In box 318, an interruptive procedure is performed to obtain the parameters during operation of the electrical system 102. The procedure selected can be one that is least interruptive or least intrusive of operations.

From either box 316 or box 318, the method proceeds to box 320. In box 320, the capacity of the battery is updated using the obtained parameters. From box 320, the method proceeds to box 322 in which the method ends.

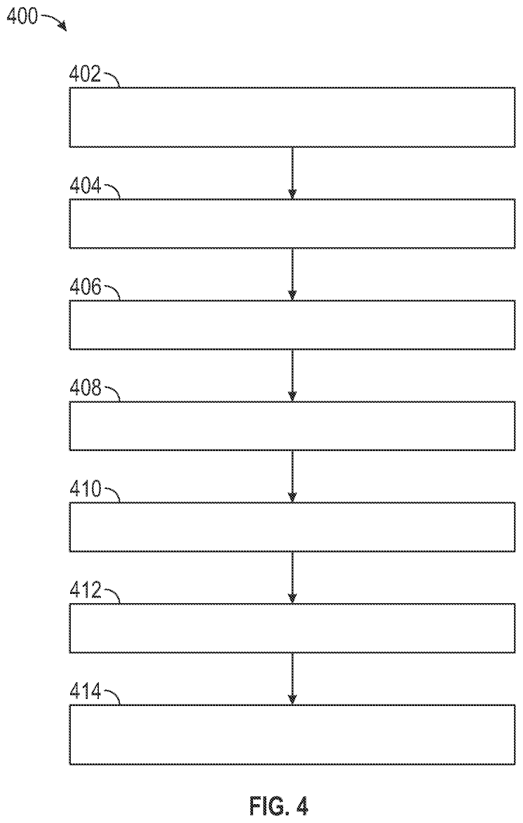

FIG. 4 is a flowchart 400 illustrating a method for testing a battery pack, in one embodiment. In various embodiments, the method can be used to test a sub-pack of a battery pack. In box 402, a contactor between the battery pack and the motor is opened to isolate the battery pack from the motor. If the contactor is already open, the contactor is prevented from closing. In box 404, with the battery pack isolated, a first state of charge (SOC_{A}) of the battery pack is calculated. In box 406, the contactor is closed. In box 408, a current throughput (I_{accum}) through the battery pack is measured while the battery pack is in use (e.g., operating the motor). In box 410, the contactor is opened to isolate the battery pack again. In box 412, a second state of charge (SOC_{B}) of the battery pack is measured. In box 414, a capacity of the battery pack is determined from the first state of charge, the second state of charge and the current throughput, as shown in Eq. (1):

$$CapCalc = \frac{{I}_{accum}}{{SOC}_{B} - {SOC}_{A}} \qquad Eq . ( 1 )$$

The method shown in flowchart 400 can be an interruptive method of data collection. In various embodiments, the method of FIG. 4 can be used to test a sub-pack of a battery pack.

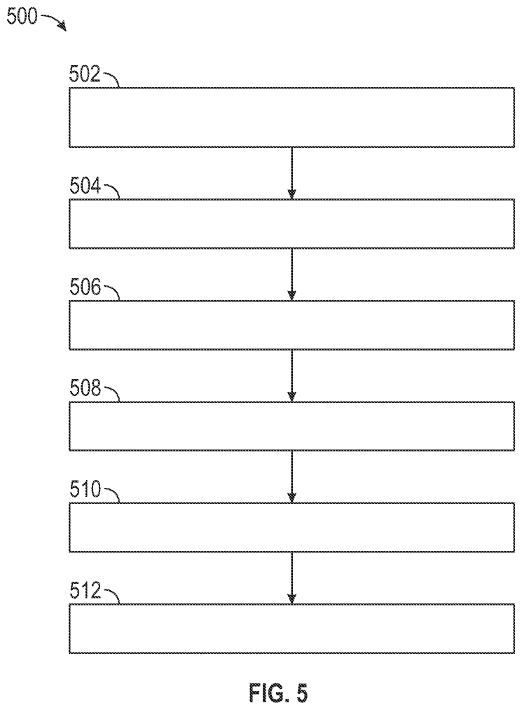

FIG. 5 is a flowchart 500 illustrating a method of determining a capacity for battery pack in another embodiment. In box 502, a current through the battery pack is brought to a steady state, such as a steady state in which the electrical system 102 is idling or near rest. In various embodiments, the steady state is zero amps. In box 504, a first voltage (V_{A}) of the battery pack is measured. In box 506, the battery is operated at an operating current level. In box 508, the current through the battery pack is once again brought to the steady state. In box 510, a second voltage (V_{B}) of the battery pack is measured. In box 512, a capacity of the battery pack is determined from the first voltage V_{A} and the second voltage V_{B}. In particular, a first SOC can be determined from the first voltage V_{A} and a second SOC can be determined from the second voltage V_{B}. The capacity of the battery pack can then be determined, for example, using Eq. (1).

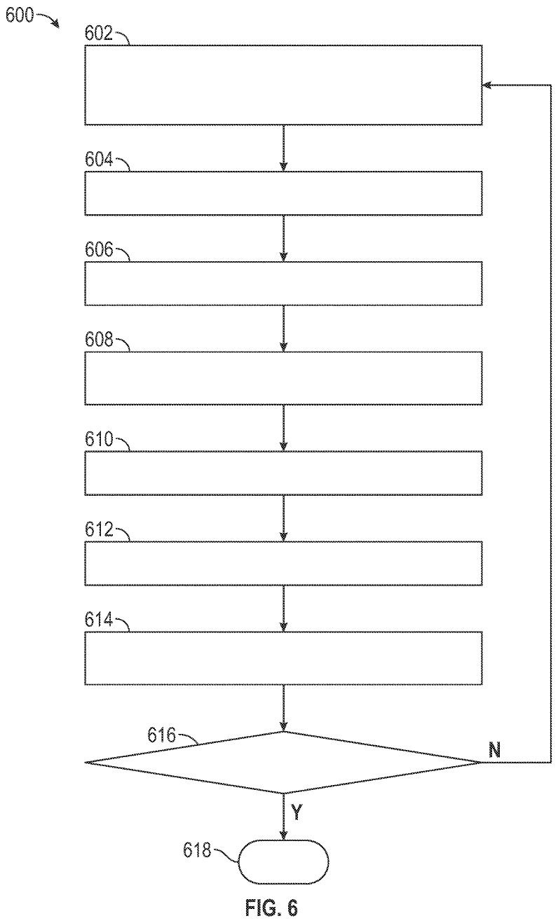

FIG. 6 is a flowchart 600 illustrating a method of testing a battery pack that is one of a plurality of battery packs of the electrical system 102. In box 602, a contactor between a selected battery pack and the load is opened to isolate the selected battery pack from the motor. If the contactor is already open, the contactor is prevented from closing. In box 604, a first state of charge (SOC_{A}) of the selected battery pack is calculated. In box 606, the contactor of the selected battery pack is closed to reconnect the selected battery pack to the electrical motor 106. In box 608, a current throughput (I_{accum}) through the selected battery pack is measured. In box 610, the contactor is opened to isolate the battery pack again. In box 612, a second state of charge (SOC_{B}) of the selected battery pack is measured. In box 614, a capacity of the battery pack is determined from the first state of charge, the second state of charge and the current throughput. In box 616, the plurality of battery packs is reviewed to determine if all data has been collected. If not all of the battery packs have been tested the method returns to box 602 and a different battery pack is selected for testing. Otherwise, at box 616, if all battery packs have been tested, the method proceeds to box 618 where the method ends. In various embodiments, the method of FIG. 6 can be used to test a sub-pack of a battery pack by isolating sub-packs individually during testing.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of operating an electrical system, comprising:
determining a model of a power schedule of the electrical system, the electrical system operating being powered by a battery pack;
determining, using the model, a test time during operation of the electrical system for obtaining a parameter suitable for calculating a capacity of the battery pack;
obtaining the parameter of the battery pack at the test time;
calculating the capacity of the battery pack using the parameter; and
operating the electrical system based on the calculated capacity.

2. The method of claim 1, further comprising obtaining the parameter using a data collection procedure that is one of: (i) interruptive of operation of the electrical system; and (ii) non-interruptive of operation of the electrical system.

3. The method of claim 1, further comprising obtaining the parameter by opening a contactor between the battery pack and the electrical system and determining a state of charge with the contactor open.

4. The method of claim 3, wherein the battery pack is selected from a plurality of battery packs, further comprising isolating a selected battery pack and obtaining the parameter of the selected battery pack while operating the electrical system using non-isolated battery packs.

5. The method of claim 1, further comprising operating the electrical system at a constant current, obtaining a first measurement of voltage, determining a current throughput of the battery pack, and obtaining a second measurement of voltage.

6. The method of claim 5, wherein the constant current is about zero amps.

7. The method of claim 1, further comprising selecting the test time from the model based on at least one of: (i) Global Positioning Satellite (GPS) telemetry; (ii) a time or distance traveled by the electrical system with no predicted changes in elevation; (iii) a time or distance travelled by the electrical system with no predicted stops; and (iv) a time or distance travelled by the electrical system with no predicted changes in load to the battery pack.

8. An electrical system, comprising:
a battery pack providing power to the electrical system;
a processor configured to:
determine a model of a power schedule of the electrical system;
determine, using the model, a test time during operation of the electrical system for obtaining a parameter suitable for calculating a capacity of the battery pack;
obtain the parameter of the battery pack at the test time;
calculate the capacity of the battery pack using the parameter; and
operate the electrical system based on the calculated capacity.

9. The electrical system of claim 8, wherein the processor is further configured to obtain the parameter using a data collection procedure that is one of: (i) interruptive of operation of the electrical system; and (ii) non-interruptive of operation of the electrical system.

10. The electrical system of claim 8, wherein the processor is further configured to obtain the parameter by opening a contactor between the battery pack and the electrical system and determine a state of charge with the contactor open.

11. The electrical system of claim 10, wherein the processor is further configured to select a battery pack from a plurality of battery packs, isolate the selected battery pack and obtain the parameter of the selected battery pack while operating the electrical system using non-isolated battery packs.

12. The electrical system of claim 8, wherein the processor is further configured to operate the electrical system at a constant current, obtain a first measurement of voltage, determine a current throughput of the battery pack, and obtain a second measurement of voltage.

13. The electrical system of claim 12, wherein the constant current is about zero amps.

14. The electrical system of claim 8, wherein the processor is further configured select the test time from the model based on at least one of: (i) Global Positioning Satellite (GPS) telemetry; (ii) a time or distance traveled by the electrical system with no predicted changes in elevation; (iii) a time or distance travelled by the electrical system with no predicted stops; and (iv) a time or distance travelled by the electrical system with no predicted changes in load to the battery pack.

15. An energy storage device operating a load, comprising:
a battery pack providing power to the load;
a processor configured to:
determine a model of a power schedule of the energy storage device;
determine, using the model, a test time during operation of the energy storage device for obtaining a parameter suitable for calculating a capacity of the battery pack;
obtain the parameter of the battery pack at the test time;
calculate the capacity of the battery pack using the parameter; and
operate the energy storage device based on the calculated capacity.

16. The energy storage device of claim 15, wherein the processor is further configured to obtain the parameter using a data collection procedure that is one of: (i) interruptive of operation of the energy storage device; and (ii) non-interruptive of operation of the energy storage device.

17. The energy storage device of claim 15, wherein the processor is further configured to obtain the parameter by opening a contactor between the battery pack and the load and determine a state of charge with the contactor open.

18. The energy storage device of claim 17, wherein the processor is further configured to select a battery pack from a plurality of battery packs, isolate the selected battery pack and obtain the parameter of the selected battery pack while operating the load using non-isolated battery packs.

19. The energy storage device of claim 15, wherein the processor is further configured to operate the energy storage device at a constant current, obtain a first measurement of voltage, determine a current throughput of the battery pack, and obtain a second measurement of voltage.

20. The energy storage device of claim 19, wherein the constant current is about zero amps.
